(19) United States
(12) Patent Application Publication
(10) Pub. No.: US 2015/0189782 A1
(43) Pub. Date: Jul. 2, 2015

(54) ELECTRICAL DEVICE HAVING A FINGERPRINT/SCRATCH PREVENTING STRUCTURE AND A METHOD OF MANUFACTURING THE SAME

(71) Applicant: Molex Incorporated, Lisle, IL (US)

(72) Inventors: Sung-Hyuk JOO, Ansan (KR); In Chull YANG, Ansan (KR)

(73) Assignee: Molex Incorporated, Lisle, IL (US)

(21) Appl. No.: 14/585,347

(22) Filed: Dec. 30, 2014

(30) Foreign Application Priority Data
Dec. 30, 2013 (KR) 10-2013-0167267

(51) Int. Cl. H05K 5/04

(52) U.S. Cl. CPC H05K 5/04

(57) ABSTRACT

An electrical device having a fingerprint/scratching prevention structure in order to prevent the occurrence of fingerprints and scratching on the surface of metal parts of electrical devices such as card sockets or connectors, etc., is disclosed. The electric device has the property of forming concavo-convex irregularities on all or part of the surface of a metal part by embossing, so that fingerprints are not left and scratches do not occur on the surface of the metal part.

### REFERENCE To RELATED APPLICATIONS

The Present Disclosure claims priority to prior-filed Korean Patent Application No. 10-2013-0167267, filed on 30 Dec. 2013 with the Korean Patent Office. The content of the aforementioned Patent Application is fully incorporated in its entirety herein.

### BACKGROUND OF THE PRESENT DISCLOSURE

The Present Disclosure relates, generally, to electrical devices, and, more specifically, to electrical devices having a scratch prevention structure, preventing the occurrence of fingerprints and scratching on the surface of metal parts of electrical devices such as card sockets or connectors, etc.

When a part of a product, made of a metal material, is disposed on the exterior of a card socket or connector, fingerprints and scratches may occur during the manufacturing process or when used by the consumer. When fingerprints or scratches occur on a metal part in this way, and especially when fingerprints or scratches occur in the manufacturing process, the marketability of the card socket or connector is impaired.

To address this problem, processes for post-processing of the smooth metal surface have been used that include attaching tape, painting, printing, hairlines (surface scratching) and laser treatment. One example of a technology employing a post-processing process on a smooth metal surface is disclosed in Republic of Korea Patent Application No. 10-2012-0022293, the content of which is hereby incorporated herein in its entirety. In the '293 Application, a hardening layer is formed by a UV coating in order to prevent the occurrence of scratches on the surface of a metal connector cover that has already been fully formed. In this case, having these characteristics, because the UV coating post-processing process is performed on the metal surface after that surface has been plated, not only is an additional process required, but because the surface is smooth, when it is used in practice, the effect in prevent fingerprints or scratches is poor.

### SUMMARY OF THE PRESENT DISCLOSURE

The purpose of the Present Disclosure, in order to resolve the aforementioned problems, is to provide an electric device having a fingerprint/scratch preventing structure that can effectively prevent the occurrence of fingerprints or scratches in use by roughening the surface of the metal part.

The electric device of the Present Disclosure has a fingerprint/scratch prevention structure with the property of forming concavo-convex irregularities on all or part of the surface of a metal part so that fingerprints are not left and scratches do not occur on the surface of the metal part. Further, the device of the Present Disclosure has a fingerprint/scratch preventing surface further comprising a plated layer formed by plating of the concavo-convex surface. The plated layer should preferably be a semi-bright layer, and the roughness of the concavo-convex surface should preferably being the range of 0.7 Ra to 2.5 Ra.

The method of manufacturing an electric device having a fingerprint/scratch preventing structure according to the Present Disclosure comprises a concavo-convexity forming step in which concavo-convexities are formed on the surface in the course of shaping a metal sheet; a plated layer formation step in which a plated layer is formed by plating of the concavo-convex surface; and a post-processing step in which part of the concavo-convexity is smoothed. In the first step, the metal sheet is formed by a rolling process, and the roller used in the rolling process is formed so as to have a rough surface. The forming of the concavo-convexity takes place only on one side or area of the metal sheet.

The electrical device having a fingerprint/scratch preventing structure and method of manufacturing the same according to the Present Disclosure has the following effects: First, by forming concavo-convexities on part or all of the surface of the metal sheet, the leaving of fingerprints and scratches on the surface of the metal sheet can be effectively prevented. Second, by semi-bright plating of the concavo-convexities, the leaving of fingerprints and scratches on the surface of the metal sheet can be further effectively prevented. Third, because concavo-convexities are formed in the rolling process by which the metal sheet is formed, rather than forming a concavo-convex part through a post-processing process after the sheet has been formed, there is no need for a separate process to form the concavo-convexities, and the cost of fabrication can be reduced as a result.

### BRIEF DESCRIPTION OF THE FIGURES

The organization and manner of the structure and operation of the Present Disclosure, together with further objects and advantages thereof, may best be understood by reference to the following Detailed Description, taken in connection with the accompanying Figures, wherein like reference numerals identify like elements, and in which:

FIG. 1 is a photograph of an electric device according to the Present Disclosure; and

FIG. 2 is a cross-section of the metal cover shown in FIG. 1.

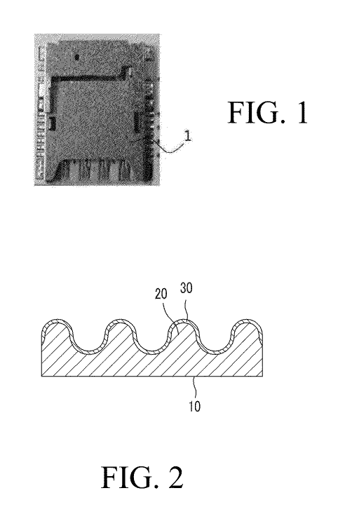

### DETAILED DESCRIPTION

While the Present Disclosure may be susceptible to embodiment in different forms, there is shown in the Figures, and will be described herein in detail, specific embodiments, with the understanding that the Present Disclosure is to be considered an exemplification of the principles of the Present Disclosure, and is not intended to limit the Present Disclosure to that as illustrated.

As such, references to a feature or aspect are intended to describe a feature or aspect of an example of the Present Disclosure, not to imply that every embodiment thereof must have the described feature or aspect. Furthermore, it should be noted that the description illustrates a number of features. While certain features have been combined together to illustrate potential system designs, those features may also be used in other combinations not expressly disclosed. Thus, the depicted combinations are not intended to be limiting, unless otherwise noted.

In the embodiments illustrated in the Figures, representations of directions such as up, down, left, right, front and rear, forward and rearward, used for explaining the structure and movement of the various elements of the Present Disclosure, are not absolute, but relative. These representations are appropriate when the elements are in the position shown in the Figures. If the description of the position of the elements changes, however, these representations are to be changed accordingly.

Referring to the Figures, the electric device having a fingerprint/scratch preventing structure according to the Present Disclosure is furnished with a metal cover 1 so as to simultaneously cover the card in the lower part and enable the insertion and removal of a card in the upper part. A metal cover 1 of this kind would be at risk of fingerprints being left or scratches occurring in the process of inserting or removing the card in the upper part, but due to the fingerprint and scratch preventing structure of the metal cover 1, there is no risk of fingerprints or scratches occurring.

The metal cover 1 comprises a metal sheet 10, concavo-convex part 20 and plated layer 30. The metal sheet 10 is fabricated through a rolling process in which the metal raw material is rolled while passing between rollers. The concavo-convex part 20 is formed so as to have a surface roughness of 0.7-2.5 on the surface of the metal sheet 10 in the process of forming the metal sheet 10 by a pressure roller that is formed with a concavo-convex surface. This concavo-convex part 20 may be formed on the entire surface of the metal plate 10, or only on one side or area.

The plated layer 30 is formed by semi-bright plating on the surface of the concavo-convex part 20. The plate material does not fill in the concave parts of the concavo-convex part 20, but rather covers both the concave and convex parts to a uniform thickness, so that the surface roughness of the concavo-convex part 20 is maintained. This plated layer 30 may be formed only on the concavo-convex part 20, or may be formed also on the parts where the concavo-convex part 20 is not formed. For the plating material, nickel, gold or tin may be used. If the surface roughness of the concavo-convex part 20 is less than 0.7 Ra, the fingerprint and scratch prevention effect will be practically nil, while if the surface roughness exceeds 2.5 Ra, the appearance will be problematically degraded.

The manufacture of an electric device like that described here typically contains the following steps:

First, the metal raw material undergoes a pressure-rolling process in which it is passed between rollers having a rough surface. The rollers used in the rolling process may be formed with concavo-convexity across the entire surface thereof, or only in a portion thereof. In addition, the rollers pressing the sheet from above and below may both be formed with concavo-convexity, or only one may be formed with concavo-convexity. In this way, according to the form of the concavo-convexity formed on the two rollers, diverse results can be selectively obtained with respect to whether the concavo-convexity is formed on both sides, one side, or only one area of the formed metal sheet. Concavo-convexity may thus be formed on the metal sheet by rolling, or alternatively concavo-convexity may be formed while shaping the metal material by several other methods such as die-casting.

After the forming of the metal sheet 10 having a concavo-convex part 20, a plated layer 30 is formed by semi-bright plating of the surface of the concavo-convex part 20. The plated layer 30 may be formed only on the part of the sheet where the concavo-convex part 20 is formed, or alternatively may be formed across the entire surface of the metal sheet 10. The plated layer 30 is formed at a uniform thickness across both the concave and convex parts of the concavo-convex part 20, rather than filling in the concave parts. The formation of the plated layer 30 is optional. In other words, if the metal plate 10 is soldered to a PCB, a plated layer can be formed, and if that is not the case, then the plated layer can be omitted.

As needed, a separate post-processing process may be employed that smoothes part of the concavo-convex part for purposes of printing in a small area, etc. The post-processing process is not a mandatory process, but an elective one that may be performed if needed. This post-processing process may be performed either before or after the plating.

A preferred embodiment of the Present Disclosure was described in detail above. However, the Present Disclosure is not limited to the embodiment described above. Various modifications and improvements are possible within the spirit of Present Disclosure described in the claims.

What is claimed is:

1. An electric device, the electric device comprising:
a metal cover, the metal cover including a metal sheet, a concavo-convex part and plated layer;
wherein concavo-convex irregularities are formed on all or part of a surface of the metal cover, preventing markings from occurring on the surface of the metal cover.

2. The electric device of claim 1, wherein the roughness of the concavo-convexity is in the range of 0.7 to 2.5 Ra.

3. The electric device of claim 1, wherein the plated layer is formed by plating the concavo-convex part.

4. The electric device of claim 3, wherein the roughness of the concavo-convexity is in the range of 0.7 to 2.5 Ra.

5. The electric device of claim 3, wherein the plated layer is a semi-bright layer.

6. The electric device of claim 5, wherein the roughness of the concavo-convexity is in the range of 0.7 to 2.5 Ra.

7. A method of manufacturing an electric device, the method comprising:
a concavo-convexity forming step in which concavo-convexities are formed on the surface of a metal sheet in the course of shaping the sheet; and
a plated layer formation step in which a plated layer is formed by plating of the concavo-convex surface.

8. The method of claim 7, wherein, at the concavo-convexity forming step, the metal sheet is formed by a rolling process.

9. The method of claim 8, wherein the roller used in the rolling process is formed with a rough surface.

10. The method of claim 9, wherein the plated layer is a semi-bright layer.

11. The method of claim 10, wherein the forming of the concavo-convexity occurs only on one side or area of the metal sheet.

12. The method of claim 11, wherein the concavo-convexity is formed so as to have a surface roughness in the range of 0.7 to 2.5 Ra.

13. The method of claim 7, further comprising a post-processing step in which part of the concavo-convexity is smoothed.
